(19) United States
(12) Patent Application Publication
(10) Pub. No.: US 2025/0201549 A1
(43) Pub. Date: Jun. 19, 2025

(54) PRECURSOR FOR FORMING SILICON-CONTAINING THIN FILM WITH HIGH HARDNESS AND LOW DIELECTRIC CONSTANT AND MANUFACTURING METHOD FOR SILICON-CONTAINING THIN FILM USING THEREOF

(71) Applicant: EGTM Co., Ltd., Suwon-si (KR)

(72) Inventors: Sung Jun Ji, Suwon-si (KR); Sun Young Baik, Incheon (KR); Tae Young Lee, Suwon-si (KR); Shin Beom Kim, Seongnam-si (KR); Woong Jin Choi, Suwon-si (KR); Kun Hee Kim, Hwaseong-si (KR)

(73) Assignee: EGTM Co., Ltd., Suwon-si (KR)

(21) Appl. No.: 18/954,021

(22) Filed: Nov. 20, 2024

(30) Foreign Application Priority Data
Dec. 14, 2023 (KR) 10-2023-0182236

(51) Int. Cl. H01L 21/02; C07F 7/18; C23C 16/30; C23C 16/50; C23C 16/56

(52) U.S. Cl. CPC H01L 21/02211; C07F 7/1804; C23C 16/30; C23C 16/50; C23C 16/56; H01L 21/02126

(57) ABSTRACT

A precursor for forming a silicon-containing thin film according to an embodiment of the present disclosure is a compound represented by the following Chemical Formula 1 or 2, in which in Chemical Formulas 1 and 2, A is a cycloalkyl group having 4 to 7 carbon atoms, R₁, R₄ and R₅ are each independently selected from hydrogen; and a substituted or unsubstituted alkyl group having 1 to 3 carbon atoms, and R₂, R₃ and R₆ are each independently an alkyl group having 1 or 2 carbon atoms.

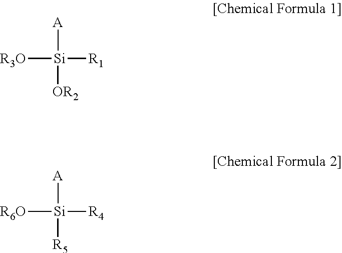

Accordingly, it is possible to provide a silicon-containing thin film with high hardness and low dielectric constant characteristics using a silicon precursor having an asymmetric structure containing a cycloalkyl group.

### CROSS-REFERENCE TO RELATED APPLICATIONS

This application claims the priority of Korean Patent Application No. 10-2023-0182236 filed on Dec. 14, 2023, in the Korean Intellectual Property Office, the disclosure of which is incorporated herein by reference.

### BACKGROUND

### Field

The present disclosure relates to a precursor for forming a silicon-containing thin film and a manufacturing method for a silicon-containing thin film using the same, and more particularly, to a silicon-containing thin film with high hardness and low dielectric constant characteristics and a manufacturing method thereof.

### Description of the Related Art

With the development of electronic technology, the demand for refinement and lightweighting of semiconductor devices used in various electronic devices is rapidly increasing. Various physical and chemical deposition methods have been proposed to form fine semiconductor devices, and various studies have been conducted to form metal-containing thin films, dielectric thin films, or the like using these deposition methods.

Meanwhile, silicon dioxide (SiO₂) or silicon oxyfluoride (SiOF), which is mainly used as an interlayer insulating film in the manufacture of semiconductor devices, has problems such as high capacitance, resistance capacitance delay (RC delay), and the like in the manufacture of ultra-high-density circuits of 0.5 μm or less. Accordingly, in order to reduce the RC delay of a multilayer metal film used in integrated circuits of the semiconductor devices, recently, research has been actively conducted on forming interlayer insulating films used in metal wirings with materials having a low dielectric constant (relative dielectric constant, k≤3.0). These thin films with a low dielectric constant are formed from inorganic materials, such as a SiCOH film mixed with Si, O, C, and H, and an amorphous carbon (a-C:F) film doped with fluorine, or from organic materials containing carbon (C).

These silicon-based thin films with the low dielectric constant may be formed by a spin-on dielectric (SOD) film or a chemical vapor deposition (CVD) process. The SOD film means an insulating film formed by coating a silicon precursor using spin-on coating and then converting the precursor into a silicon oxide film through heat treatment (e.g., at 300° C. to 600° C.). In the case of the insulating film formed as such, there were problems such as poor thermal stability due to a relatively low heat-resistant limit temperature (about 450° C. or less), volume shrinkage occurring after heat treatment, and low mechanical strength. In addition, there are problems such as poor adhesion with upper and lower wiring materials, high stress caused by thermal curing, and a change in dielectric constant due to adsorption of ambient moisture, which reduces the reliability of the device.

In the CVD process, a thin film may be formed by a heat-induced chemical reaction between a precursor and a reactive gas on the substrate surface. Accordingly, the deposition process is performed under a high temperature condition, and in this case, there was a problem in that the structure of the device having the layer formed on the substrate was damaged due to the high temperature.

To solve these problems, plasma enhanced chemical vapor deposition (PECVD) has been proposed to deposit metal and dielectric thin films at a relatively low temperature.

In the PECVD process, radiofrequency (RF) energy is applied to a reaction zone to promote excitation and/or dissociation of reactive gases, thereby generating highly reactive species of plasma. Due to the high reactivity of the plasma generated in this way, the energy required to cause a chemical reaction is reduced. Therefore, in the PECVD process, the temperature required for forming the thin film formation may be lowered. Due to the introduction of these devices and methods, the size of the structure of the semiconductor device has been significantly reduced.

### SUMMARY

Silicon precursors used to form conventional silicon thin films with a low dielectric constant include octamethylcyclotetrasiloxane (OMCTS), diethoxymethylsilane (DEMS), tetraethoxyorthosilicate (TEOS), etc. These precursors exist in a liquid state at room temperature, making the process easy, but have a disadvantage of low hardness due to the formation of large, unevenly distributed pores within the thin film. As a result, the mechanical strength of the thin film was insufficient, which caused various difficulties in manufacturing semiconductor devices and limited the scope of application.

Therefore, an object of the present disclosure is to provide a thin film with high hardness and low dielectric constant having excellent mechanical strength while having a low dielectric constant, and a manufacturing method for the same.

The objects of the present disclosure are not limited to the aforementioned objects, and other objects, which are not mentioned above, will be apparent to those skilled in the art from the following description.

A precursor for forming a silicon-containing thin film according to an embodiment of the present disclosure is represented by the following Chemical Formula 1 or 2.

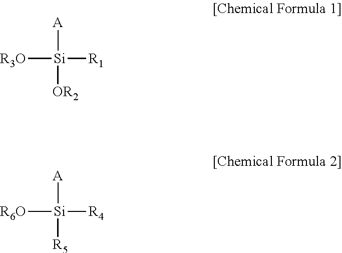

In Chemical Formulas 1 and 2, A is a cycloalkyl group having 4 to 7 carbon atoms, R₁, R₄ and R₅ are each independently selected from hydrogen; and a substituted or unsubstituted alkyl group having 1 to 3 carbon atoms, and R₂, R₃ and R₆ are each independently an alkyl group having 1 or 2 carbon atoms.

The silicon-containing thin film according to an embodiment of the present disclosure is manufactured by depositing the precursor.

A manufacturing method for a silicon-containing thin film according to an embodiment of the present disclosure includes depositing a silicon precursor represented by Chemical Formula 1 or 2 above on a substrate by plasma enhanced chemical vapor deposition (PECVD).

Details of other embodiments will be included in the detailed description of the invention and the accompanying drawings.

According to the embodiment of the present disclosure, the silicon precursor represented by Chemical Formula 1 or 2 is a silicon compound having an asymmetric structure containing a cycloalkyl group, and when the silicon precursor is used to form a silicon thin film, it is possible to provide a thin film with high hardness and low dielectric constant having excellent mechanical strength while having a low dielectric constant. In addition, it is possible to form a silicon-containing thin film with high hardness and low dielectric constant by using a single silicon precursor without separately supplying a material such as porogen.

In addition, the silicon compound having the asymmetric structure containing the cycloalkyl group according to an embodiment of the present disclosure has a high vapor pressure at a low process temperature, thereby enabling smooth supply of reactive gases to the substrate surface during thin film deposition.

In addition, the silicon precursor according to an embodiment of the present disclosure can be easily decomposed when energy is applied in a thin film formation process, and thus, has advantages that it is possible to form a thin film having a low dielectric constant characteristic and to easily control a binding ratio of Si—CH₃ within the thin film.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 illustrates results of H-NMR analysis of a silicon precursor manufactured according to Example 1;

FIG. 2 illustrates results of H-NMR analysis of a silicon precursor manufactured according to Example 2;

FIG. 3 illustrates results of thermo gravimetric analysis of a silicon precursor manufactured according to Example 1; and

FIG. 4 illustrates results of thermo gravimetric analysis of a silicon precursor manufactured according to Example 2.

### DETAILED DESCRIPTION OF THE EMBODIMENT

Advantages and features of the present disclosure, and methods for accomplishing the same will be more clearly understood from embodiments to be described below in detail with reference to the accompanying drawings. However, the present disclosure is not limited to the following embodiments but may be implemented in various different forms. The embodiments are provided only to complete disclosure of the present disclosure and to fully provide a person having ordinary skill in the art to which the present disclosure pertains with the category of the invention.

In describing the present disclosure, a detailed description of related known technologies will be omitted if it is determined that they unnecessarily make the gist of the present disclosure unclear. The terms such as “including”, “having”, and “consisting of” used herein are generally intended to allow other components to be added unless the terms are used with the term “only”. When a component is expressed in a singular form, the singular form may include a plural form unless expressly stated otherwise.

Components are interpreted to include an ordinary error range even if not expressly stated.

A silicon precursor for forming a silicon-containing thin film according to an embodiment of the present disclosure may be represented by Chemical Formula 1 or 2 below.

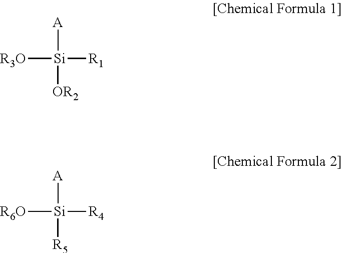

R₁ in Chemical Formula 1, and R₄ and R₅ in Chemical Formula 2 may each be independently selected from hydrogen and an alkyl group having 1 to 3 carbon atoms. For example, R₁ in Chemical Formula 1, and R₄ and R₅ in Chemical Formula 2 may each be independently selected from a methyl group and an ethyl group. Preferably, for example, R₁ in Chemical Formula 1, and R₄ and R₅ in Chemical Formula 2 may each be a methyl group. In this case, a thin film with a high deposition rate may be formed while a deposition process is easy due to a low vapor pressure.

For example, the alkyl group having 1 to 3 carbon atoms may be substituted with one or more substituents of an amino group, a hydroxyl group, a cyano group, a halogen group, a nitro group, and an alkoxy group, but is not limited thereto.

R₂ and R₃ in Chemical Formula 1 and R₆ in Chemical Formula 2 may each independently be an alkyl group having 1 or 2 carbon atoms. For example, R₂ and R₃ in Chemical Formula 1 and R₆ in Chemical Formula 2 may each be a methyl group. In this case, a thin film with a high deposition rate may be formed while a deposition process is easy due to a low vapor pressure.

In Chemical Formulas 1 and 2, A is a cycloalkyl group having 4 to 7 carbon atoms. The cycloalkyl group is a functional group with a cyclic saturated hydrocarbon structure, and forms nano-pores within the thin film during thin film deposition, thereby providing a silicon-containing thin film with excellent hardness and low dielectric constant characteristics. In addition, the cyclic saturated hydrocarbon may include a plurality of C—Hx bond structures to provide a thin film with excellent mechanical strength and elasticity.

If necessary, optionally, the cycloalkyl group having 4 to 7 carbon atoms may further include a substituent. For example, the cycloalkyl group having 4 to 7 carbon atoms may be substituted with one or more substituents of an alkyl group of 1 to 6 carbon atoms, an amino group, a hydroxyl group, a cyano group, a halogen group, a nitro group, and an alkoxy group, but is not limited thereto.

For example, in Chemical Formulas 1 and 2, A may be each independently selected from a cyclopentyl group and a cyclohexyl group. In this case, the silicon thin film formed of the silicon precursor represented by Chemical Formula 1 or 2 has the advantages of being thermally stable, having a low dielectric constant, and having excellent hardness.

For example, the precursor for forming the silicon thin film may be selected from cyclopentyl diethoxy methyl silane, cyclopentyl dimethyl ethoxy silane, cyclohexyl dimethoxy methyl silane, and cyclohexyl dimethyl methoxy silane. In this case, the thin film formed during deposition has superior hardness and also has a low dielectric constant to be used in various devices.

Specifically, for example, the silicon precursor may be selected from compounds represented by Chemical Formulas 3 and 4 below.

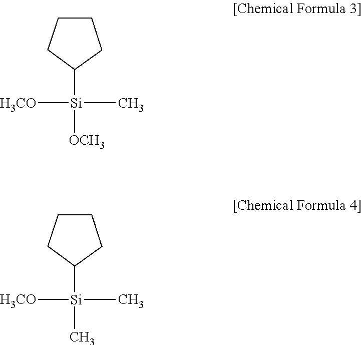

Silicon precursors according to Chemical Formulas 3 and 4 have an asymmetric structure in which a bulky cyclopentyl group or cyclohexyl group, a methoxy group and a methyl group are bonded to Si. Accordingly, nano-pores are effectively formed on the substrate during deposition. The thin film formed in this way is thermally stable, has nanopores formed by the bulky cyclopentyl or cyclohexyl group, and has a low dielectric constant characteristic. Accordingly, the thin film has the advantage of being suitable for semiconductor devices due to excellent mechanical strength, high hardness, and low dielectric characteristics. In addition, the thin film formed from the silicon precursor of the present disclosure may maintain effective low dielectric characteristics even when power is increased.

According to the present disclosure, when manufacturing a silicon-containing thin film, a silicon-containing thin film with high hardness and low dielectric constant may be formed using only a silicon precursor of Chemical Formula 1 and/or 2 without adding auxiliary materials such as a porogen compound. Specifically, since the silicon precursors of Chemical Formulas 1 and 2 according to the present disclosure contain a cycloalkyl group, nano-pores may be formed inside the thin film without using a compound such as porogen in addition to the silicon precursor.

In addition, the silicon precursor of the present disclosure is a single molecule with an asymmetric structure containing one silicon atom in one molecule, and has a low vapor pressure, so that it is possible to form a thin film at a high deposition rate during the deposition process. Accordingly, it is possible to form a silicon thin film that has a lower dielectric constant while satisfying mechanical strength required in semiconductor processes.

In addition, there is an advantage in that the carbon content in the silicon-containing thin film may be easily controlled as needed, thereby making it possible to easily manufacture a thin film having a desired dielectric constant while improving mechanical strength.

In addition, the thin film formed using the silicon precursor of Chemical Formulas 1 and 2 according to the present disclosure is suitable for a semiconductor device manufacturing process due to thermal stability and a low dielectric constant characteristic at a very low level. In addition, the thin film with the low dielectric constant may be provided to be used by replacing a dielectric layer used in metal multilayer wirings of conventional semiconductor devices. In this case, it is possible to improve the performance of the device by improving a resistance-capacitance signal delay that increases with the miniaturization and integration of metal multilayer wirings.

As described above, the silicon precursor according to the present disclosure contains one silicon atom in one molecule. Therefore, the silicon precursor has the characteristic of low vapor pressure. For example, the silicon precursors represented by Chemical Formulas 1 and 2 may have a vapor pressure of 0.03 mmHg to 0.2 mmHg at 25° C.

As such, since the silicon precursors have low vapor pressure characteristics, the silicon precursors of Chemical Formulas 1 and 2 may be easily supplied to a reactor in a vapor phase when forming a thin film through a plasma enhanced chemical vapor deposition (PECVD) process. Specifically, the silicon precursors of Chemical Formulas 1 and 2 of the present disclosure may be advantageously used to supply precursors to the reactor using a bubbler canister. Furthermore, it is possible to provide a silicon-containing thin film having an excellent deposition rate.

In addition, the silicon precursors of Chemical Formulas 1 and 2 include a cyclic saturated hydrocarbon structure, which may provide a thin film with excellent mechanical strength and improved elasticity by containing a large number of C—Hx structures.

The precursors of Chemical Formulas 1 and 2 may be used for forming a silicon-containing thin film. For example, the silicon-containing thin film may be formed by depositing the precursors of Chemical Formulas 1 and/or 2 onto a substrate using a PECVD process. The PECVD method generates plasma of highly reactive species to effectively decompose and excite the silicon precursors, which may react with reactive gases to be polymerized on a substrate to form a silicon-containing thin film.

The silicon-containing thin film formed above may include an SiOCH film. Specifically, for example, a silicon-containing thin film deposited using a silicon precursor in which A is a cyclopentyl group in Chemical Formulas 1 and 2 may include an SiOCH film having a structure represented by the following Chemical Formula A. However, the present disclosure is not limited thereto.

The SiOCH film having the structure represented by Chemical Formula A may form nanopores inside the thin film due to a cyclopentyl group, which is a cyclic hydrocarbon functional group, and may include a plurality of C—Hx bond structures due to the cyclic hydrocarbon.

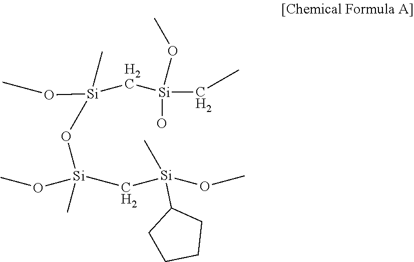

For example, the thickness of the silicon-containing thin film may be 0.1 μm to 0.5 μm. In addition, the silicon-containing thin film has excellent mechanical strength while having a low dielectric constant due to a uniform distribution of micropores with nanometer sizes of less. Accordingly, the silicon-containing thin film may be advantageously used as a dielectric layer between multilayer metal wirings in the semiconductor device.

Hereinafter, a process for depositing the silicon-containing thin film on the substrate by plasma enhanced chemical vapor deposition using silicon precursors of Chemical Formulas 1 and 2 will be described in detail.

A manufacturing method for a silicon-containing thin film with high hardness and low dielectric constant includes supplying and stabilizing a substrate to a plasma deposition reactor, supplying silicon precursors represented by Chemical Formulas 1 and/or 2 to the reactor, forming a silicon-containing thin film on the substrate by polymerizing the silicon precursors using plasma, and post-processing the thin film.

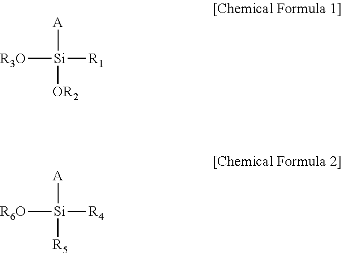

The silicon precursors represented by Chemical Formulas 1 and 2 are the same as those described above, and thus the duplicated description will be omitted.

First, the supplying and stabilizing of the substrate to the plasma deposition reactor is a step of supplying the substrate to a reaction chamber of the plasma deposition reactor and removing impurities from the upper portion of the substrate and the inside of the chamber. For example, after supplying the substrate, an inert gas such as argon or helium may be purged inside the chamber to remove impurities. However, the present disclosure is not limited thereto. As such, a high-quality thin film may be formed by removing the impurities to suppress the generation of by-products due to side reactions. After removing the impurities, the inside of the chamber is kept under a vacuum state for reaction.

Next, the silicon precursors represented by Chemical Formulas 1 and/or 2 are supplied to the reactor. For example, the silicon precursors may be supplied in a bubbling manner using a bubbler canister.

Specifically, the silicon precursors represented by Chemical Formulas 1 and/or 2 are supplied into the bubbler canister, and when the bubbler canister is heated, the silicon precursors may be vaporized within the bubbler canister. The vaporized silicon precursors may flow through a transport pipe and be injected into the reactor.

If necessary, optionally, the silicon precursors may be supplied together with a carrier gas or dilution gas. The carrier gas is not reactive with the silicon precursor and is lighter than the silicon precursor, so that it is possible to easily transport the vaporized silicon precursor to the reaction chamber. The dilution gas has no reactivity with the silicon precursor so as not to cause side reactions, and the flow rate thereof may be controlled to easily control the reaction such as a growth rate of the thin film, etc.

For example, the carrier gas or dilution gas may include one or more selected from argon (Ar), helium (He), and neon (Ne).

The carrier gas or dilution gas may also be supplied by bubbling using a bubbler canister, but is not limited thereto. The supplied carrier gas or dilution gas may be transported through the transport pipe together with the vaporized silicon precursor and injected into the reactor. At this time, the pressure of the carrier gas inside the reactor may be 1×10⁻¹ Torr to 100×10⁻¹ Torr, but is not limited thereto.

The next step is to supply the reaction gas to the reactor. For example, the reaction gas includes at least one of nitrogen monoxide (N₂O) and oxygen (O₂). The reaction gas may react with the silicon precursors of Chemical Formulas 1 and 2 to form a high-quality thin film.

The next step is to form a silicon-containing thin film by reacting and depositing the silicon precursors on the substrate using plasma.

Plasma particles may be formed by supplying the silicon precursors and the reaction gas into the reactor and applying high-frequency energy through an RF power source connected to the substrate. As such, the activated silicon precursors and the reaction gas may chemically react to form a silicon-containing thin film including an SiOCH film.

In the forming of the silicon-containing thin film, the temperature of the substrate may be 300° C. to 400° C. Within this range, the reaction between the activated silicon precursors and the reaction gas is easy, and a high-quality silicon-containing thin film may be formed. However, the present disclosure is not limited thereto.

In the forming of the silicon-containing thin film, the power supplied to the reactor may be 10 W to 40 W. The thin film can be formed within this range, and if the power is less than 10 W or more than 40 W, a thin film having a desired level of high hardness and a low dielectric constant characteristic may not be formed. However, the present disclosure is not limited thereto.

The next step is to post-process the polymer thin film. For example, the post-processing may be performed by any one of an inductively coupled plasma (ICP) treatment process, a rapid thermal annealing (RTA) process, or a combination thereof. By forming and then post-processing the thin film in this way, the dielectric constant of the silicon-containing thin film may be further reduced.

The manufacturing method for the silicon-containing thin film with high hardness and low dielectric constant according to an embodiment of the present disclosure generates plasma of highly reactive species to effectively decompose and excite the silicon precursors of Chemical Formulas 1 and 2. As such, the decomposed and excited precursors may perform various chemical reactions, and react with reaction gas to form a silicon thin film on the substrate. The silicon-containing thin film manufactured in this way has a low dielectric constant due to the formation of nano-sized pores by the cycloalkyl group contained in the silicon precursor. In addition, the thin film has excellent mechanical strength by including a plurality of C—Hx bond structures.

Accordingly, according to the present disclosure, it is possible to manufacture a silicon-containing thin film with high hardness and low dielectric constant using a single silicon precursor without adding an auxiliary substance such as porogen.

Hereinafter, the effects of the present disclosure will be described in more detail through Examples. However, these Examples are only presented to aid the understanding of the present disclosure, and the present disclosure is not limited to the following Examples.

### Example 1

### 1) Preparation of Precursor

In a flame-dried 2 L Schlenk flask, 100 g (0.525 mol) of cyclopentyl trimethoxy silane and 1 L of n-hexane were added and stirred at room temperature. 169.5 ml (0.525 mol) of a methyllithium solution (3.1 M methyllithium in diethoxymethane) was added dropwise to the flask at 0° C. or below, and then the reaction solution was stirred at room temperature for 12 hours. A lithium salt produced after the reaction was filtered through a filter, and then distilled under reduced pressure after the solvent was removed under reduced pressure to obtain 36.63 g (yield 40%) of a colorless, transparent liquid compound, cyclopentyl dimethoxy methyl silane.

### 2) Manufacturing of Silicon-Containing Thin Film

Using a PECVD device, a silicon wafer was placed on an RF electrode inside a reactor and maintained in a vacuum state of 10-2 Torr. Next, the cyclopentyl dimethoxy methyl silane prepared above as a silicon precursor was added into a bubbler canister and heated to 75° C. to vaporize a precursor solution. Argon (Ar) and helium (He) gases with 99.999% ultra-high purity were used as carrier gas. The carrier gas passed through the bubbler canister and the transport pipe, and was injected with the silicon precursor through a showerhead of the reactor, and added with oxygen (O₂) as reaction gas to perform plasma deposition on the substrate. At this time, an AC power of 13.56 Hz and 40 W or less was supplied to generate plasma, and plasma polymerization was performed at a pressure of 1.0 Torr or less and a temperature of 400° C. or less. Through this, a thin film with a thickness of 4000 Å was manufactured.

### Example 2

### 1) Preparation of Precursor

In a flame-dried 2 L Schlenk flask, 100 g (0.525 mol) of cyclopentyl trimethoxy silane and 1 L of n-hexane were added and stirred at room temperature. 355.95 ml (1.103 mol) of a methyllithium solution (3.1 M methyllithium in diethoxymethane) was added dropwise to the flask at 0° C. or below, and then the reaction solution was stirred at room temperature for 12 hours. A lithium salt produced after the reaction was filtered through a filter, and then distilled under reduced pressure after the solvent was removed under reduced pressure to obtain 35.77 g (yield 43%) of a colorless, transparent liquid compound, cyclopentyl methoxy dimethylsilane.

### 2) Manufacturing of Silicon-Containing Thin Film

A thin film was manufactured in the same manner as in Example 1, except that cyclopentyl methoxy dimethyl silane prepared in Example 2 was used as the silicon precursor.

### Comparative Example 1

Using a PECVD device, a silicon wafer was placed on an RF electrode inside a reactor and maintained in a vacuum state of 10-2 Torr. Next, cyclopentyl trimethoxy silane (CPTMS) of Chemical Formula 1a as a silicon precursor was added in a bubbler canister and heated to 75° C. to vaporize a precursor solution. Argon (Ar) and helium (He) gases with 99.999% ultra-high purity were used as carrier gas. The carrier gas passed through the bubbler canister and the transport pipe, and the silicon precursor was injected into the reactor through a showerhead of the reactor. Plasma was deposited on the substrate by introducing oxygen (O₂) as reaction gas. At this time, an AC power of 13.56 Hz and 40 W or less was supplied to generate plasma, and plasma polymerization was performed at a pressure of 1.0 Torr or less and a temperature of 400° C. or less.

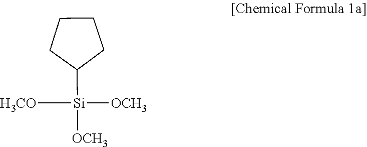 [SMILES: CO[Si](OC)(OC)C1CCCC1]

### Experimental Examples

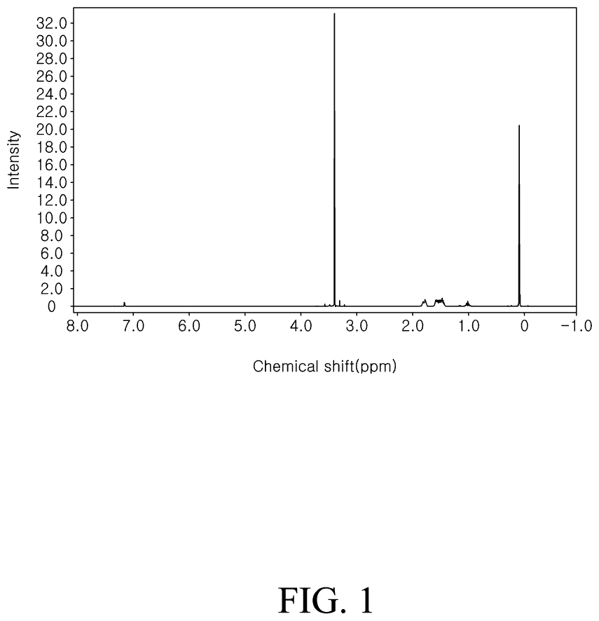

The refractive indexes of silicon thin films manufactured according to Example 1, Example 2, and Comparative Example 1 were measured, and FT-IR and H-NMR analyses of silicon precursors were performed. The results were shown in Table 1 below and FIGS. 1 to 4.

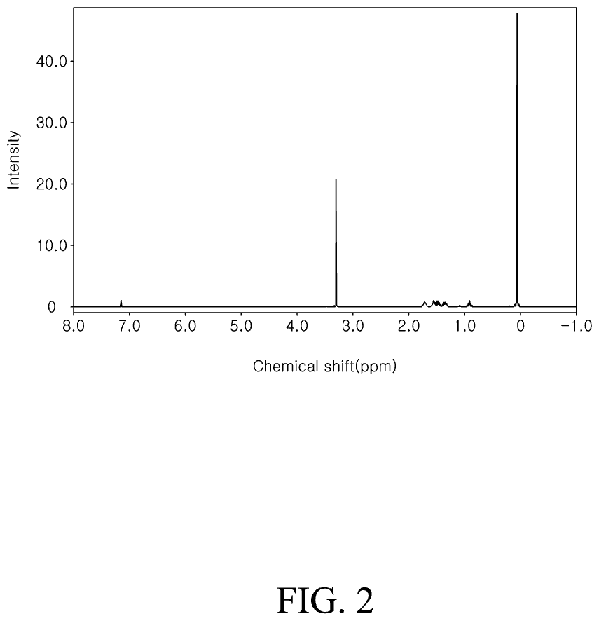

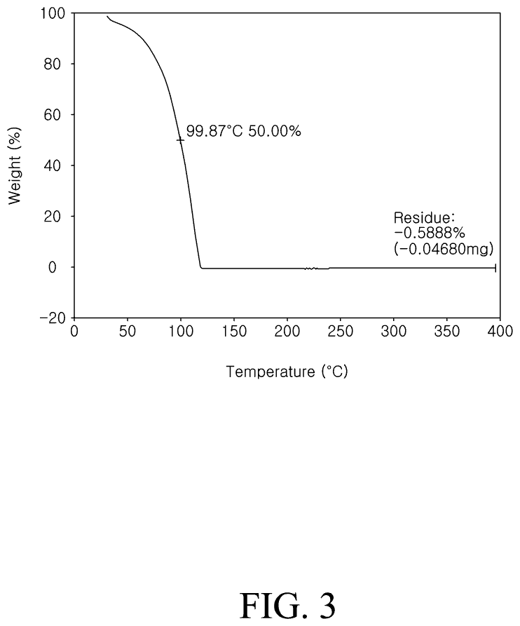

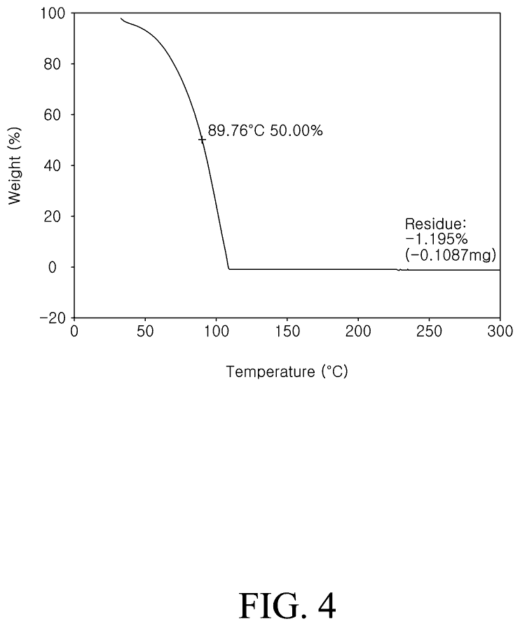

FIG. 1 illustrates results of H-NMR analysis of a silicon precursor manufactured according to Example 1, FIG. 2 illustrates results of H-NMR analysis of a silicon precursor manufactured according to Example 2, FIG. 3 illustrates results of thermo gravimetric analysis of a silicon precursor manufactured according to Example 1, and FIG. 4 illustrates results of thermo gravimetric analysis of a silicon precursor manufactured according to Example 2.

TABLE 1

| | Refractive | FT-IR main peak | | | | |
|---|---|---|---|---|---|---|
| | Index | | | Sub- | | |
| | (R.I) | Cage | Network | oxide | Si—CH₃ | CxHy |
| Comparative | 1.506 | 22.3 | 40.3 | 34.6 | 0.5 | 2.2 |
| Example 1 | | | | | | |
| Example 1 | 1.472 | 21.5 | 34.1 | 29.2 | 1.8 | 1.7 |
| Example 2 | 1.424 | 25.42 | 24.6 | 33.00 | 2.74 | 0.83 |

First, referring to FIGS. 1 and 2, the synthesis of cyclopentyl dimethoxy methyl silane according to Example 1 and cyclopentyl methoxy dimethyl silane according to Example 2 may be confirmed from the H-NMR analysis results.

Referring to FIG. 3, it can be confirmed that the silicon precursor of Example 1 has a T_{1/2} of about 100° C., and the silicon precursor of Example 2 has a T_{1/2} of about 90° C., and that the half-life of Example 2, which has a greater number of methyl groups, is lower. From this, it can be seen that when the silicon precursor of Example 2 is used, the silicon precursor is easily vaporized during the deposition process, which is relatively advantageous for the process.

Meanwhile, referring to Table 1, as the FT-IR analysis results, it can be confirmed that as the number of methyl groups increases, the ratio of Si—CH₃ bonds increases. Accordingly, it can be confirmed that the Si—CH₃ bond ratios of Examples 1 and 2 are higher than that of Comparative Example 1, and that Example 2 has the highest Si—CH₃ bond ratio. In addition, it can be confirmed that the higher the Si—CH₃ bond ratio, the lower the refractive index. Accordingly, it can be confirmed that Examples 1 and 2 have lower refractive indices than Comparative Example 1, and that Example 2 has the lowest refractive index.

Through this, it can be seen that when using the silicon precursors according to Examples 1 and 2, it is possible to form a thin film with high hardness and low dielectric constant having superior mechanical strength and a lower dielectric constant value compared to when using the precursor of Comparative Example 1.

The precursor for forming the silicon-containing thin film, the silicon-containing thin film, and the manufacturing method for the silicon-containing thin film according to various embodiments of the present disclosure may be described as follows.

A precursor for forming a silicon-containing thin film according to an embodiment of the present disclosure is represented by the following Chemical Formula 1 or 2.

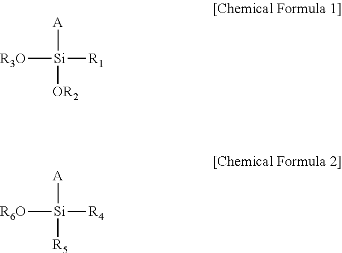

In Chemical Formulas 1 and 2, A is a cycloalkyl group having 4 to 7 carbon atoms, R₁, R₄ and R₅ are each independently selected from hydrogen; and a substituted or unsubstituted alkyl group having 1 to 3 carbon atoms, and R₂, R₃ and R₆ are each independently an alkyl group having 1 or 2 carbon atoms.

According to another feature of the present disclosure, the precursor may have a vapor pressure of 0.03 mmHg to 0.2 mmHg at 25° C.

According to yet another feature of the present disclosure, in Chemical Formulas 1 and 2, A may each independently be a cyclopentyl group or a cyclohexyl group.

According to yet another feature of the present disclosure, the precursor may be selected from cyclopentyl diethoxy methyl silane, cyclopentyl dimethyl ethoxy silane, cyclohexyl dimethoxy methyl silane, and cyclohexyl dimethyl methoxy silane.

According to yet another feature of the present disclosure, the precursor may be selected from compounds represented by Chemical Formulas 3 and 4 below.

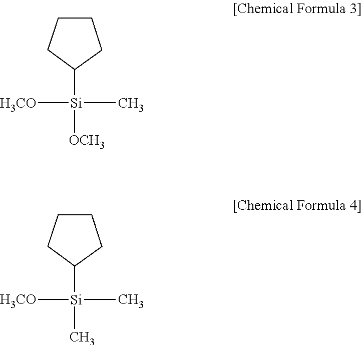

The silicon-containing thin film according to an embodiment of the present disclosure is manufactured by depositing the precursor.

According to another feature of the present disclosure, the thickness of the thin film may be 0.1 μm to 0.5 μm.

According to yet another feature of the present disclosure, the thin film may be formed by plasma enhanced chemical vapor deposition (PECVD).

According to yet another feature of the present disclosure, the thin film may include an SiOCH film.

A manufacturing method for a silicon-containing thin film according to an embodiment of the present disclosure includes depositing a silicon precursor represented by Chemical Formula 1 or 2 below on a substrate by plasma enhanced chemical vapor deposition (PECVD).

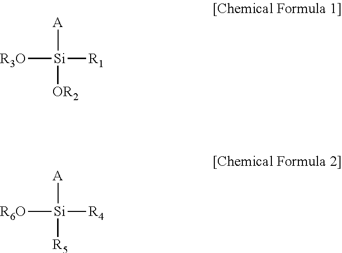

In Chemical Formulas 1 and 2, A is a cycloalkyl group having 4 to 7 carbon atoms, R₁, R₄ and R₅ are each independently selected from hydrogen; and a substituted or unsubstituted alkyl group having 1 to 3 carbon atoms, and R₂, R₃ and R₆ are each independently an alkyl group having 1 or 2 carbon atoms.

According to another feature of the present disclosure, the depositing on the substrate may include supplying the silicon precursor to a reactor and depositing the silicon precursor on the substrate by irradiating plasma to form a silicon-containing thin film.

According to yet another feature of the present disclosure, the method may further include supplying reaction gas to the reactor before irradiating the plasma.

According to yet another feature of the present disclosure, the reaction gas may include at least one of nitrogen monoxide (N₂O) and oxygen (O₂).

According to yet another feature of the present disclosure, the silicon-containing thin film may include an SiOCH film.

According to yet another feature of the present disclosure, after the forming of the silicon-containing thin film, the method may further include post-processing the thin film, and the post-processing may be performed by any one of an inductively coupled plasma (ICP) treatment process, a rapid thermal annealing (RTA) process, or a combination thereof.

Although the embodiments of the present disclosure have been described in detail with reference to the accompanying drawings, the present disclosure is not limited thereto and may be embodied in many different forms without departing from the technical concept of the present disclosure. Accordingly, the various embodiments disclosed in the present disclosure are not intended to limit the technical spirit but describe the present disclosure and the technical spirit of the present disclosure is not limited by the following embodiments. Therefore, it should be understood that the above-described embodiments are illustrative in all aspects and do not limit the present disclosure. The protective scope of the present disclosure should be construed on the basis of the appended claims, and all the technical ideas in the equivalent scope thereof should be construed as falling within the scope of the present disclosure.

What is claimed is:

1. A precursor for forming a silicon-containing thin film represented by the following Chemical Formula 1 or 2: 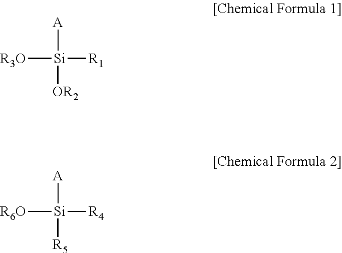
in Chemical Formulas 1 and 2,
A is a cycloalkyl group having 4 to 7 carbon atoms,
R₁, R₄ and R₅ are each independently selected from hydrogen; and a substituted or unsubstituted alkyl group having 1 to 3 carbon atoms, and
R₂, R₃ and R₆ are each independently an alkyl group having 1 or 2 carbon atoms.

2. The precursor for forming the silicon-containing thin film of claim 1, wherein the precursor has a vapor pressure of 0.03 mmHg to 0.2 mmHg at 25° C.

3. The precursor for forming the silicon-containing thin film of claim 1, wherein in Chemical Formulas 1 and 2, A is each independently a cyclopentyl group or a cyclohexyl group.

4. The precursor for forming the silicon-containing thin film of claim 1, wherein the precursor is selected from cyclopentyl diethoxy methyl silane, cyclopentyl dimethyl ethoxy silane, cyclohexyl dimethoxy methyl silane, and cyclohexyl dimethyl methoxy silane.

5. The precursor for forming the silicon-containing thin film of claim 1, wherein the precursor is selected from compounds represented by Chemical Formulas 3 and 4 below:

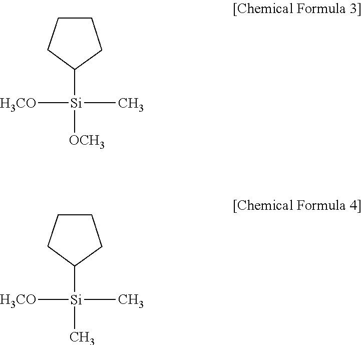

6. A silicon-containing thin film manufactured by depositing the precursor according to claim 1.

7. The silicon-containing thin film of claim 6, wherein a thickness of the thin film is 0.1 μm to 0.5 μm.

8. The silicon-containing thin film of claim 6, wherein the thin film is formed by plasma enhanced chemical vapor deposition (PECVD).

9. The silicon-containing thin film of claim 6, wherein the thin film includes an SiOCH film.

10. A manufacturing method for a silicon-containing thin film comprising: depositing a silicon precursor represented by Chemical Formula 1 or 2 below on a substrate by plasma enhanced chemical vapor deposition (PECVD): 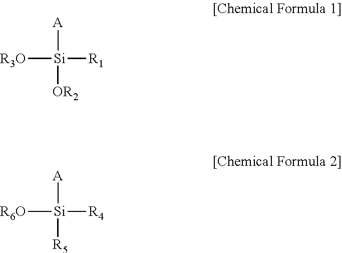
in Chemical Formulas 1 and 2,
A is a cycloalkyl group having 4 to 7 carbon atoms,
R₁, R₄ and R₅ are each independently selected from hydrogen; and a substituted or unsubstituted alkyl group having 1 to 3 carbon atoms, and
R₂, R₃ and R₆ are each independently an alkyl group having 1 or 2 carbon atoms.

11. The manufacturing method for the silicon-containing thin film of claim 10, wherein the depositing on the substrate includes:
supplying the silicon precursor to a reactor; and
depositing the silicon precursor on the substrate by irradiating plasma to form the silicon-containing thin film.

12. The manufacturing method for the silicon-containing thin film of claim 11, further comprising:
supplying reaction gas to the reactor before irradiating the plasma.

13. The manufacturing method for the silicon-containing thin film of claim 12, wherein the reaction gas includes at least one of nitrogen monoxide (N₂O) and oxygen (O₂).

14. The manufacturing method for the silicon-containing thin film of claim 11, wherein the silicon-containing thin film includes an SiOCH film.

15. The manufacturing method for the silicon-containing thin film of claim 11, further comprising:
post-processing the thin film, after the forming of the silicon-containing thin film,
wherein the post-processing is performed by any one of an inductively coupled plasma (ICP) treatment process, a rapid thermal annealing (RTA) process, or a combination thereof.

16. A silicon-containing thin film manufactured by depositing the precursor according to claim 2.

17. A silicon-containing thin film manufactured by depositing the precursor according to claim 3.

18. A silicon-containing thin film manufactured by depositing the precursor according to claim 4.

19. A silicon-containing thin film manufactured by depositing the precursor according to claim 5.
